(19) United States
(12) Patent Application Publication
(10) Pub. No.: US 2025/0211247 A1
(43) Pub. Date: Jun. 26, 2025

(54) APPARATUS, METHOD, BASE STATION, AND MOBILE USER EQUIPMENT FOR PROCESSING UNDERSAMPLED SIGNAL

(71) Applicant: Intel Corporation, Santa Clara, CA (US)

(72) Inventors: Albert MOLINA, Novelda (ES); Kannan RAJAMANI, Basking Ridge, NJ (US)

(21) Appl. No.: 18/393,867

(22) Filed: Dec. 22, 2023

(51) Int. Cl. H03M 1/12

(52) U.S. Cl. CPC H03M 1/1245; H03M 1/1235

(57) ABSTRACT

An apparatus for processing an undersampled digital input signal, comprises an input node configured to receive the undersampled digital input signal. A first circuitry is configured to perform a bandpass interpolation on the undersampled digital input signal to generate an interpolated digital signal using an interpolation factor depending on a Nyquist zone M selected from multiple Nyquist zones, M being greater than 1. A non-linear equalizer generates an equalized signal from the interpolated digital signal. A second circuitry is configured to downsample the equalized signal to a sample rate of the undersampled digital input signal.

### BACKGROUND

A continuous analog signal is sampled at discrete time intervals to generate a digital representation of the analog signal. However, considering that power consumption is proportional to a sampling rate of an analog-to-digital converter (ADC), sampling a bandpass signal at Nyquist rate may cause a significant power consumption. Undersampling the analog signal is one approach to reduce power consumption. However, it may not be an optimal choice applying signal processing techniques appropriate for a signal sampled at Nyquist rate to process an undersampled signal. Hence, there may be a demand for improved undersampled signal processing.

### BRIEF DESCRIPTION OF THE FIGURES

Some examples of apparatuses and/or methods will be described in the following by way of example only, and with reference to the accompanying figures, in which

FIG. 1 illustrates a block diagram of an example of an apparatus for processing an undersampled digital input signal;

FIG. 2 illustrates an example of the apparatus for performing bandpass interpolation on the undersampled digital input signal;

FIG. 3 illustrates another example of the apparatus for performing bandpass interpolation on the undersampled digital input signal;

FIG. 4 illustrates a spectrum of an exemplary analog signal and Nyquist zones at different sample rates;

FIG. 5 illustrates contributions of a non-linearity to the spectrum of an exemplary signal passing through a non-linear system;

FIG. 6 illustrates an example of an apparatus using a conventional approach to process a digital input signal;

FIG. 7 illustrates exemplary regions of the spectrum for signals fully occupying Nyquist Zones 2, 3 and 4 and affected by non-linear functions of orders 2, 3, 4 and 5;

FIG. 8 illustrate a block diagram of an example of a circuitry;

FIG. 9 illustrates an example of a base station;

FIG. 10 illustrates an example of a mobile user equipment; and

FIG. 11 illustrates a flowchart of an exemplary method for processing the undersampled digital input signal.

### DETAILED DESCRIPTION

Various examples will now be described more fully with reference to the accompanying drawings in which some examples are illustrated. In the figures, the thicknesses of lines, layers and/or regions may be exaggerated for clarity.

Accordingly, while further examples are capable of various modifications and alternative forms, some particular examples thereof are shown in the figures and will subsequently be described in detail. However, this detailed description does not limit further examples to the particular forms described. Further examples may cover all modifications, equivalents, and alternatives falling within the scope of the disclosure. Like numbers refer to like or similar elements throughout the description of the figures, which may be implemented identically or in modified form when compared to one another while providing for the same or a similar functionality.

It will be understood that when an element is referred to as being “connected” or “coupled” to another element, the elements may be directly connected or coupled or via one or more intervening elements. If two elements A and B are combined using an “or”, this is to be understood to disclose all possible combinations, i.e. only A, only B as well as A and B. An alternative wording for the same combinations is “at least one of A and B”. The same applies for combinations of more than 2 Elements.

The terminology used herein for the purpose of describing particular examples is not intended to be limiting for further examples. Whenever a singular form such as “a”, “an” and “the” is used and using only a single element is neither explicitly or implicitly defined as being mandatory, further examples may also use plural elements to implement the same functionality. Likewise, when a functionality is subsequently described as being implemented using multiple elements, further examples may implement the same functionality using a single element or processing entity. It will be further understood that the terms “comprises,” “comprising,” “includes” and/or “including,” when used, specify the presence of the stated features, integers, steps, operations, processes, acts, elements and/or components, but do not preclude the presence or addition of one or more other features, integers, steps, operations, processes, acts, elements, components and/or any group thereof.

Unless otherwise defined, all terms (including technical and scientific terms) are used herein in their ordinary meaning of the art to which the examples belong.

An apparatus 100 for processing an undersampled digital input signal will be explained in the following with reference to FIGS. 1 to 3.

FIG. 1 illustrates an example of the apparatus 100 for processing the undersampled digital input signal 101 (Yₙ). The apparatus 100 comprises an input node 110 configured to receive the undersampled digital input signal 101. Undersampling may be understood as a signal sampling at a sample rate below its Nyquist rate. Nyquist rate may be understood as a sampling rate equal to twice a highest frequency of a given signal.

The apparatus 100 comprises a first circuitry 197 configured to perform a bandpass interpolation on the undersampled digital input signal 101 to generate an interpolated signal 102 (\tilde{Y}ₙ) using an interpolation factor depending on a Nyquist zone M selected from multiple Nyquist zones, M being greater than 1. For the undersampled digital input signal 101, the lowest and highest frequencies are denoted as F_{L} and F_{H}, respectively. A bandwidth B and center frequency F_{C} of the signal 101 are given as B=F_{H}−F_{L} and F_{C}=(F_{L}+F_{H})/2, respectively. Nyquist zone M may be understood as a range of frequencies which satisfies the following condition:

$$( M - 1 ) \frac{{F}_{S}}{2} \leq \vert F \vert < M \frac{{F}_{S}}{2}$$

where Fₛ indicates the sampling frequency. To avoid aliasing, it is sufficient that M be constrained to:

$$1 \leq M \leq ⌊ \frac{{F}_{H}}{B} ⌋$$

Interpolation may be understood as a process of resampling an input signal at a higher rate than the input signal sample rate by an integer factor, which may insert an intermediate or multiple intermediate values between two adjacent original samples depending on the integer interpolation factor. In the example of FIG. 1, the first circuitry 197 is followed by a non-linear equalizer 198 configured to generate an equalized signal 103 (\tilde{Z}ₙ) from the interpolated digital signal 102. The equalized signal is transmitted to a second circuitry 199 configured to downsample the equalized signal to a sample rate of the undersampled digital input signal 101 and output a downsampled signal 104 (Zₙ). Downsampling may be understood as a process of reducing an input signal at a lower rate than the input signal sample rate.

As an example, by choosing a higher Nyquist zone than a first Nyquist zone or Nyquist zone 1, a sample rate of a non-linear device, such as Analog-to-Digital Converter, ADC, can be lower than that of Nyquist zone 1. In other words, undersampling may be implemented. Since a power consumption of an ADC is proportional to the sample rate of the ADC, it may cause reduction in power consumption by utilizing lower sample rate than Nyquist rate.

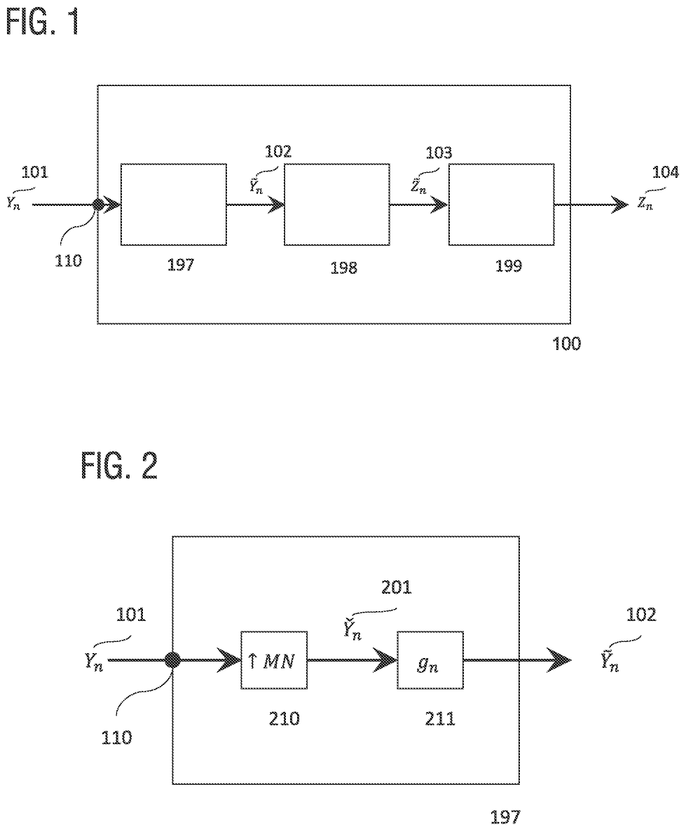

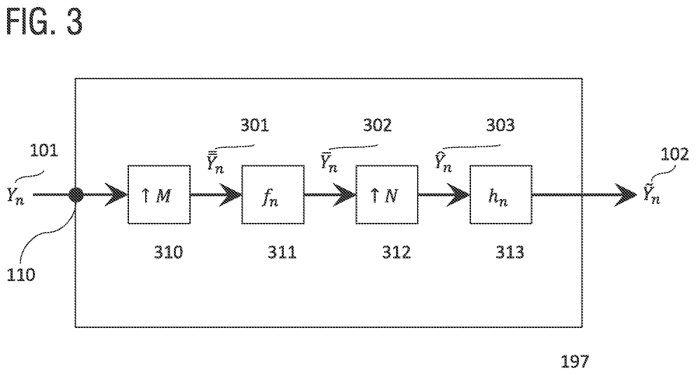

A derivation of the structure of the first circuitry 197 will be given below with respect to FIGS. 2 and 3.

FIG. 2 illustrates an alternative representation of the first circuitry 197 comprised in the apparatus 100 illustrated in FIG. 1 for processing the undersampled digital input signal 101. The alternative representation comprises the input node 110 to receive the undersampled digital input signal 101.

Further, the first circuitry 197 comprises an upsampling circuitry 210 configured to upsample the undersampled digital input signal 101 by the factor MN and a filter 211 configured to limit a bandwidth of the upsampled digital input signal 201 (\tilde{Y}ₙ). Upsampling may be understood as a process of resampling an input signal at a higher rate than the input signal sample rate by an integer factor, which inserts zeros between the two adjacent samples of the input signal. Filtering followed by the upsampling may be understood as a process of replacing the zeros with new non-zero sample values. Alternatively, interpolation may be understood as a combination of upsampling and filtering a signal. As an example, the filter 211 may be a bandpass filter, which limits a bandwidth of an output signal to a specified band of frequencies and block components with frequencies above or below this band. The filter 211 allows to select the Nyquist zone of interest by limiting the bandwidth of the upsampled digital input signal 201. The interpolated signal 102 is processed following the steps described in the example of FIG. 1.

FIG. 3 illustrates another representation of the first circuitry 197 comprised in the apparatus 100 illustrated in FIG. 1 for processing the undersampled digital input signal 101. The alternative representation comprises the input node 110 to receive the undersampled digital input signal 101.

In the example of FIG. 3, another extension of the first circuitry 197 comprises a chain of upsampling blocks and filters. The undersampled digital input signal 101 is upsampled via an upsampling circuitry 310 generating a first upsampled digital input signal 301 (Y̅ₙ). A first filter 311 coupled to the upsampling circuitry 310 outputs a bandwidth limited signal 302 (Y̅ₙ) from the first upsampled digital input signal 301. A second upsampling circuitry 312 is followed by the first filter 311, configured to upsample the bandwidth limited signal 302 generating a second upsampled digital input signal 303 (Ŷₙ). As an example, an upsampling factor M in the upsampling circuitry 310 corresponds to Nyquist zone M, where the spectrum of the input signal is. The first filter 311 may be a high-pass filter, which passes signals with frequencies higher than a certain cutoff frequency and attenuates signals with frequencies lower than the cutoff frequency. An upsampling factor N in the second upsampling circuitry 312 may correspond to the maximum order of a non-linearity that shall be corrected within the undersampled digital input signal 101. The interpolated digital input signal 102 is generated via a second filter 313 by limiting its bandwidth. The second filter 313 may be a low-pass filter, which passes signals with a frequency lower than a certain cutoff frequency and attenuates signals with frequencies higher than the cutoff frequency. The interpolated signal 102 is processed following the steps described in the example of FIG. 1.

In FIG. 3, a bandpass filter may be a combination of a high-pass filter and a low-pass filter. The final interpolation factor is MN, which equivalent to the interpolation factor of the interpolating circuitry 210 in FIG. 2. Hence, the interpolated signal 102 generated by the first circuitry 197 in FIG. 2 and the interpolated signal 102 generated by the first circuitry 197 in FIG. 3 are interpolated to the same extent. The first circuitry 197 is configured to perform a bandpass interpolation by upsampling the undersampled digital input signal 101 and filtering the upsampled signal 201 in order to select a Nyquist zone by limiting the bandwidth of the the upsampled signal 201.

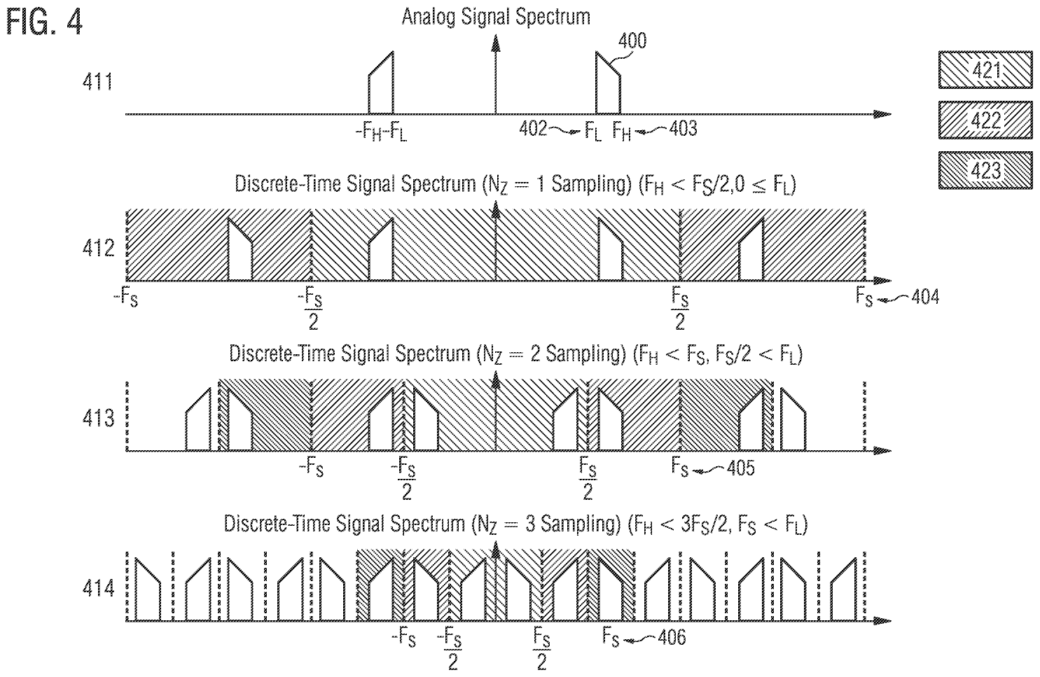

Nyquist zone M and order of non-linearity N will be further explained below in the context of FIG. 1 to 3 with respect to FIG. 4 to 7.

FIG. 4 illustrates a relationship between a sampling rate and Nyquist zones by comparing spectra of an analog signal 400 sampled at different sampling rates. The analog signal 400 may be understood as a continuous-time signal with a finite range of frequencies between a lower cutoff frequency F_{L} and an upper cutoff frequency F_{H}. An analog-to-digital-converter, ADC, uses the analog signal and converts it into a discrete digital signal. A sampling rate or an ADC sampling rate may be understood as the number of samples taken per second. The spectrum of the analog signal is concentrated at the set of frequencies F_{A} that satisfies the following condition:

$$\vert f + ( 1 - 2 q ) {F}_{C} \vert \leq \frac{1}{2} B , \qquad q ∈ ( 0 , 1 )$$

where f∈F_{A}, F_{C} denotes the center frequency of the analog signal, and B is a bandwidth of the analog signal defined as B=F_{H}−F_{L}.

When the analog signal 400 is sampled, a sampled digital signal from the analog signal is replicated by multiples of the sample rate. The discrete-time signal spectrum content is at nF_{S}+F_{A}, where n is an integer. The spectrum is divided into regions called Nyquist zones. Nyquist zone covers the following range of frequencies:

$$( M - 1 ) \frac{{F}_{S}}{2} \leq \vert F \vert < M \frac{{F}_{S}}{2}$$

where M denotes Mth Nyquist zone or Nyquist zone M.

Aliasing occurs when sampling replicas overlap. To avoid aliasing, the complete spectrum of the analog signal is contained within a single Nyquist zone.

The respective sampling rate Fₛ for a given Nyquist zone M is given by:

$$\frac{{F}_{H}}{M} < \frac{{F}_{S}}{2} < \frac{{F}_{L}}{M - 1}$$

In FIG. 4, as an example, Nyquist zone 1 to 3 are depicted. Each Nyquist zone contains a replica of the spectrum of the desired signal or a mirror image of it. The order of Nyquist zones to be considered is not limited to 3.

At a first sampling rate 404, the spectrum of the analog signal 400 is within in a first Nyquist zone 421 or Nyquist zone 1 as illustrated in a discrete-time signal spectrum 412 in FIG. 4. The input signal spectrum coincides with Nyquist zone 1 discrete-time spectrum. At a second sampling rate 405, the sampling rate is half of the first sampling rate 404, which places the analog signal in a second Nyquist zone 422 or Nyquist zone 2. Note that, even though there is no aliasing, the spectrum seen in Nyquist zone 1 after sampling is flipped relative to the original spectrum. At a third sampling rate 406, the sampling rate is quarter of the first sampling rate 404, which places the analog signal in a third Nyquist zone 423 or Nyquist zone 3. The spectrum seen after sampling is not flipped relative to the original spectrum.

In order to reconstruct the sampled digital input signal, a bandpass filter may be used, configured to select an appropriate replica located around ±F_{C}. In the context of FIGS. 2 and 3, the first circuitry 197 provides a mean to limit the bandwidth of the undersampled digital input signal 101.

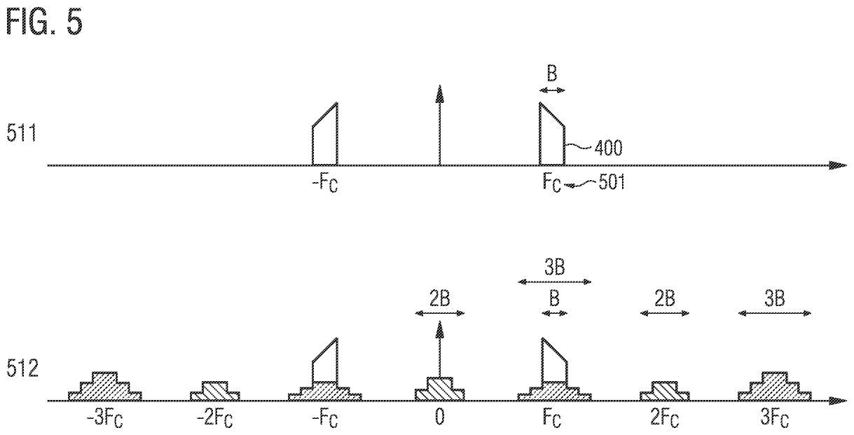

FIG. 5 illustrates effects of a non-linear system on an analog signal sampling. The spectrum of the analog signal mentioned in the context of FIG. 4, is expanded after passing through a non-linear system comprising a non-linearity term of order k. A range of frequencies of the sampled digital signals comprising the non-linearity may be given as follows:

$$\vert f + ( k - 2 q ) {F}_{C} \vert \leq \frac{k}{2} B , \qquad q ∈ ( 0 ⋯ k )$$

As an example, non-linear terms of order 2 and 3 are selectively illustrated in FIG. 5. The underlying analog signal 400 with a center frequency 501 (F_{C}) and bandwidth B is illustrated in 511 in FIG. 5. After passing through the non-linear system with non-linearity of order 2 and 3, the output is illustrated in a discrete-time spectrum 512 in FIG. 5. The spectra with bandwidth 2B around 0 Hz and 2F_{C} show non-linear terms of order 2. The spectra around F_{C} comprise a desired digital signal with bandwidth B and non-linear terms of order 3. The spectra around 3F_{C} shows non-linear terms of order 3.

That is, the presence of non-linearities may result in the spectrum of the digital signal being extended across the borders of a single Nyquist zone.

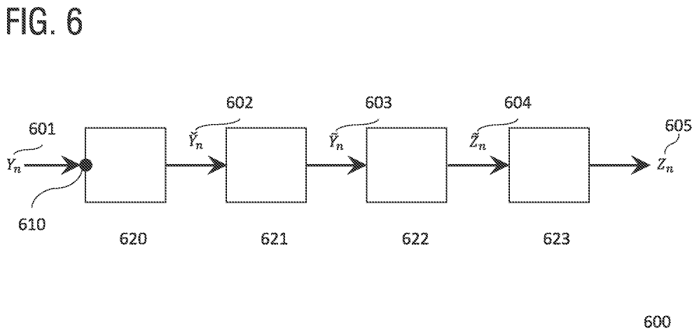

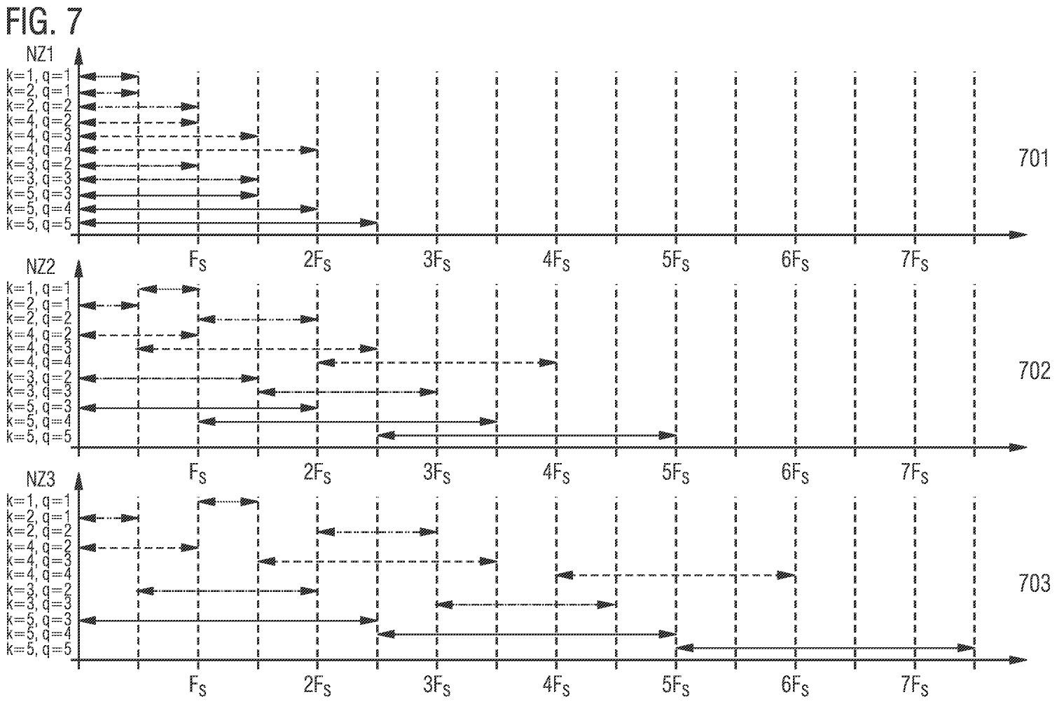

Two different cases to cancel or remove non-linear terms of the digital input signal wherein the analog signal is within Nyquist zone 1 and any Nyquist zone M where M>1 will be given with respect to FIG. 6 and FIG. 7.

FIG. 6 illustrates an exemplary conventional approach to process a digital input signal 601 (Yₙ). An apparatus 600 is configured to process the digital input signal 601 derived from an analog signal within Nyquist zone 1. Hence, interpolation does not consider a factor depending on the Nyquist zone but only on the order of non-linearity N. Non-linear components generated from the undistorted analog signal may be estimated and cancelled. A sampling rate to position the analog signal within Nyquist zone 1 is F_{S}≥2F_{H}, where F_{S} is a sample rate of a non-linear device or an ADC as an example and F_{H} is the highest frequency of the analog signal. Since the highest frequency of the non-linear components of the digital input signal is kₘₐₓF_{H}, where kₘₐₓ is the highest non-linear order, the frequencies above F_{S}/2 are folded back into Nyquist zone 1. Nonetheless, the non-linear components can be estimated and cancelled by means of a non-linear equalizer 622 as shown in FIG. 6. The digital input signal 601 is received via an input node 610 and is upsampled by a factor of N≥kₘₐₓ by an upsampling circuitry 620. Resultant upsampled digital input signal 602 (Y̌ₙ) is input into a filter 621 to limit the spectrum of the upsampled digital input signal to Nyquist zone 1 by selecting a range of frequencies below a cutoff frequency. The respected interpolated signal 603 (\tilde{Y}ₙ) is then transmitted to a non-linear equalizer 622. The non-linear equalizer 622 comprises a sum of weighted non-linear functions that generates an estimate of non-linearity and output an equalized signal 604 (\tilde{Z}ₙ). The equalized signal 604 is decimated back to the sample of the digital input signal by a downsampling circuitry 623, which generates a downsampled signal 605 (Zₙ). When the equalized signal 604 is decimated back to the original sampling rate, the estimate of the non-linearity is folded into Nyquist zone 1 in the same way as the original non-linearities are folded by the ADC sampling process, in such a way that the original non-linearities are canceled. A non-linear equalizer can have a similar structure as a non-linear system or ADC.

When the analog signal is contained within any single Nyquist zone M different from M=1, replicas of the analog signal generated by the sampling process via ADC in Nyquist zone 1 does not coincide with the analog signal before the digital signal sampling. The non-linear terms generated from this Nyquist zone 1 replica are not equivalent to the non-linear terms generated from the analog signal. This will be explained in more detail below with respect to FIG. 7.

FIG. 7 illustrates exemplary spectral regions for each non-linear order k, where k∈(1 . . . 5), and for a given center frequency F_{C} and bandwidth B. If the analog signal is within Nyquist zone 1, there is an overlap between the non-linear regions q=1 and q=2 of k=2 as shown in graph 701. However, if the analog signal is within Nyquist zone 2, then there is no overlap between the non-linear regions q=1 and q=2 of k=2 as illustrated in graph 702. As an example, a given analog signal is within Nyquist zone 2 and it is sampled at a sample rate of F_{S}. If a digital input signal derived from the analog signal is processed as described in FIG. 6, then the replica of the analog signal within Nyquist zone 1 will be used to generate the non-linear cancelation signal. However, as shown in 702, the non-linear components generated within Nyquist zone 2 are different from those within Nyquist zone 1 as illustrated in 701.

Similarly, there are differences between non-linear components of a digital input signal when an analog signal is within different Nyquist zone and passes through a non-linear device with different non-linear order of k. Hence, if the analog signal is within Nyquist zone other than 1, both the order of Nyquist zone M and the order of non-linearity N are considered as factors to process an undersampled digital input signal.

In the context of FIGS. 2 and 3, the undersampled digital input signal 101 is upsampled by a interpolation factor MN, where N≥kₘₐₓ where kₘₐₓ denotes a highest order of non-linearity, and M is equal to or higher than Nyquist zone Mᵣₑₐₗ wherein the analog signal is. In FIG. 2, the filter 211 after upsampling the undersampled digital input signal 101 by MN is a bandpass filter that selects the Nyquist zone where the analog signal is and replaces zeros with non-zero values after upsampling process. In FIG. 3, a combination of the first filter 311 and the second filter 313 is used to selects the Nyquist zone where the analog signal is and replaces zeros with non-zero values after upsampling process. The output of the non-linear equalizer is decimated by MN to return to the original sampling rate. Since the input to the non-linear equalizer is in the same region as the original input signal to which the non-linearity was applied, the cancellation signal generated by the non-linear equalization appropriately cancels the non-linearities comprised in the undersampled digital input signal 101.

As described within the context of FIGS. 1 to 3, selecting Nyquist zone M, where M is greater than 1, enables using a lower sample rate than that used to select the analog signal within Nyquist zone 1 or Nyquist rate, where M=1, which may reduce power consumption since power consumption is proportional to a sample rate of an undersampled digital input signal.

In some conditions, even though the analog signal is within a Nyquist zone Mᵣₑₐₗ, different Nyquist zone M, where M<Mᵣₑₐₗ, may be chosen as an interpolation factor MN. In the absence of spectral overlap between different regions of the non-linearity, it is possible to generate non-linear components cancellation signal. A condition for no overlap between the non-linear regions (p=0 . . . k) for a non-linearity of order k is given as follows:

2F_{c}≥kB

where F_{C} is a center frequency of the analog signal. When the analog signal occupies the full Nyquist zone, then the bandwidth of the analog signal can be written as B=F_{S}/2 and F_{C}=(M−0.5)F_{S}/2, and hence the condition for no spectra overlap is as follows:

k≤(2M−1)

For the non-linear equalizer which corrects non-linear terms up to order of k and for the case wherein the analog signal may occupy the full Nyquist zone, in other words the bandwidth of the analog signal, may be as large as F_{S}/2, the smallest M can be used, which follows the equation above.

For the case where the input signal bandwidth is less than F_{S}/2, a Nyquist zone M may be used, which satisfies the following relationship 2F_{c}≥kB wherein F_{c} corresponds to a center frequency of a signal replica of the analog signal in Nyquist zone M.

It enables using smaller interpolation factor MN by choosing a smaller M value than Mᵣₑₐₗ, which may reduce complexity of interpolating, equalizing, and downsampling processes.

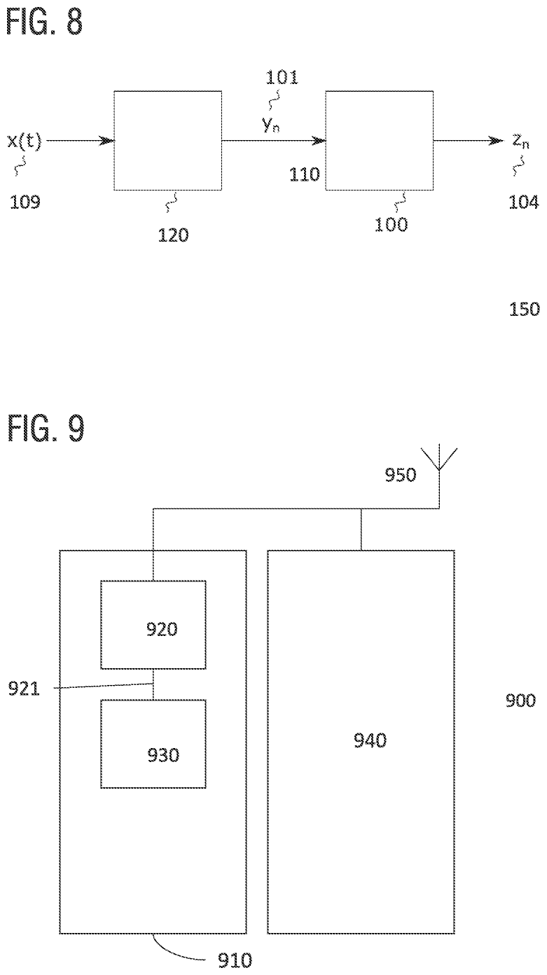

FIG. 8. illustrates a circuitry 150 comprising a non-linear system 120 such as an ADC, coupled to the apparatus 100. The non-linear system 120 is configured to output the undersampled digital input signal 101. The circuitry 150 further comprises a receiver configured to provide a time-continuous analog signal 109 (x(t)) to the non-linear system 120.

The analog signal 109 may be distorted by the non-linear system 120. The undersampled digital input signal 101 generated by the non-linear system 120 may comprise non-linear terms. The undersampled digital signal 101 is an input signal for the apparatus 100 via the input node 110. The apparatus 100 is configured to process the undersampled digital input signal 101 and output a downsampled signal 104 as described above with respect to FIGS. 1 to 7.

As an example of an implementation using undersampled digital input signal processing according to one or more examples described above in connection with FIGS. 1 to 8, a base station of a mobile communication network is illustrated in FIG. 9.

FIG. 9 schematically illustrates an example of a base station 900 (e.g. for a femtocell, a picocell, a microcell or macrocell) comprising an apparatus 930 for processing undersampled digital input signal 921 as proposed.

The base station 900 comprises at least one antenna element 950. A receiver 910 of the base station 900 comprises the apparatus 930 and is coupled to the antenna element 950. For example, the receiver 910 may be coupled to the antenna element 950 via one or more intermediate element such as a Low-Noise Amplifier (LNA), a filter, a down-converter (mixer), ElectroStatic Discharge (ESD) protection circuitry, an attenuator etc.

Additionally, the receiver 910 comprises a non-linear system 620 coupled to the apparatus 930. The non-linear system 920 provides the undersampled digital input signal 921. The non-linear system 920 may, e.g., configured to generate the undersampled digital input signal 921 based on a Radio Frequency (RF) receive signal received from the antenna element 950 or another antenna element (not illustrated) of the base station 900. The non-linear system 920 may be or comprise an ADC configured to output the digital input signal 921. The non-linear system 920 may comprise on or more further element such as an LNA, a filter, a down-converter (mixer), ESD protection circuitry, an attenuator, etc.

Additionally, the base station 900 comprises a transmitter 940 configured to generate an RF transmit signal. The transmitter 940 may use the antenna element 950 or another antenna element (not illustrated) of the base station 900 for radiating the RF transmit signal to the environment. For example, the transmitter 940 may be coupled to the antenna element 950 via one or more intermediate elements such as a filter, an up-converter (mixer) or a Power Amplifier (PA).

To this end, a base station with improved undersampled digital signal processing may be provided allowing the base station to meet high performance targets at lower power consumption and lower area consumption.

The base station 900 may comprise further elements such as, e.g., an application processor, memory, a network controller, a user interface, a power management circuitry, a satellite navigation receiver, a network interface controller, or a power tee circuitry.

In some aspects, the application processor may include one or more Central Processing Unit (CPU) cores and one or more of cache memory, a Low-DropOut (LDO) voltage regulator, interrupt controllers, serial interfaces such as Serial Peripheral Interface (SPI), Inter-Integrated Circuit (I²C) or universal programmable serial interface module, Real Time Clock (RTC), timer-counters including interval and watchdog timers, general purpose Input-Output (IO), memory card controllers such as Secure Digital (SD)/MultiMedia Card (MMC) or similar, Universal Serial Bus (USB) interfaces, Mobile Industry Processor Interface Alliance (MIPI) interfaces and Joint Test Access Group (JTAG) test access ports.

In some aspects, the baseband processor may be implemented, for example, as a solder-down substrate including one or more integrated circuits, a single packaged integrated circuit soldered to a main circuit board or a multi-chip module containing two or more integrated circuits.

In some aspects, the memory may include one or more of volatile memory including Dynamic Random Access Memory (DRAM) and/or Synchronous Dynamic Random Access Memory (SDRAM), and Non-Volatile Memory (NVM) including high-speed electrically erasable memory (commonly referred to as Flash memory), Phase change Random Access 30 Memory (PRAM), Magnetoresistive Random Access Memory (MRAM) and/or a three-dimensional crosspoint (3D XPoint) memory. The memory may be implemented as one or more of solder down packaged integrated circuits, socketed memory modules and plug-in memory cards.

In some aspects, the power management integrated circuitry may include one or more of voltage regulators, surge protectors, power alarm detection circuitry and one or more back-up power sources such as a battery or capacitor. Power alarm detection circuitry may detect one or more of brown out (under-voltage) and surge (over-voltage) conditions.

In some aspects, the power tee circuitry may provide for electrical power drawn from a network cable to provide both power supply and data connectivity to the base station using a single cable.

In some aspects, the network controller may provide connectivity to a network using a standard network interface protocol such as Ethernet. Network connectivity may be provided using a physical connection which is one of electrical (commonly referred to as copper interconnect), optical or wireless.

In some aspects, the satellite navigation receiver module may include circuitry to receive and decode signals transmitted by one or more navigation satellite constellations such as the Global Positioning System (GPS), GLObalnaya NAvigatSionnaya Sputnikovaya Sistema (GLONASS), Galileo and/or BeiDou. The receiver may provide data to the application processor which may include one or more of position data or time data. The application processor may use time data to synchronize operations with other radio base stations.

In some aspects, the user interface may include one or more of physical or virtual buttons, such as a reset button, one or more indicators such as Light Emitting Diodes (LEDs) and a display screen.

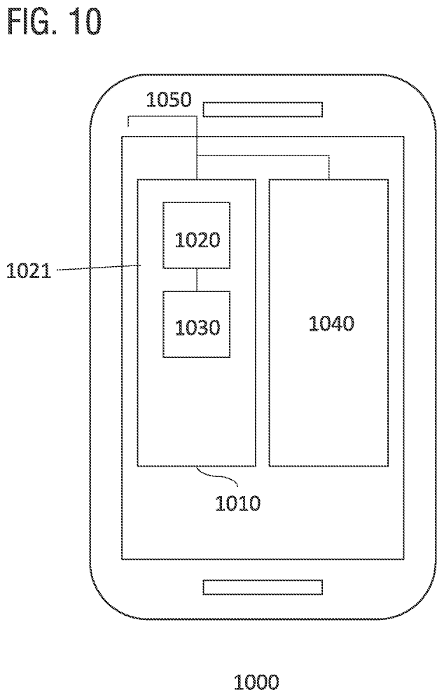

Another example of an implementation using the undersampled digital input signal processing according to one or examples described above in connection with FIGS. 1 to 8 is illustrated in FIG. 10.

FIG. 10 schematically illustrates an example of a mobile device 1000 (e.g. mobile phone, smartphone, tablet computer, or laptop) comprising an apparatus 1030 for processing an undersampled digital input signal 1021 as proposed.

The mobile user equipment 1000 comprises at least one antenna element 1050. A receiver 1010 of the mobile user equipment 1000 comprises the apparatus 1030 and is coupled to the antenna element 1050.

For example, the receiver 1010 may be coupled to the antenna element 1050 via one or more intermediate element such as a LNA, a filter, a down-converter (mixer), ESD protection circuitry, an attenuator etc.

Additionally, the receiver 1010 comprises a non-linear system 1020 coupled to the apparatus 1030. The non-linear system 1010 provides the undersampled digital input signal 1021. The non-linear system 1020, e.g. ADC, may be configured to generate the undersampled digital input signal 1021 based on an RF receive signal received from the antenna element 1050 or another antenna element (not illustrated) of the mobile user equipment 1000. The non-linear system 1020 may be or comprise an ADC configured to output the undersampled digital input signal 1021. The non-linear system 1020 may comprise one or more further element such as a LNA, a filter, a down-converter (mixer), ESD protection circuitry, an attenuator, etc.

Additionally, the mobile user equipment 1000 comprises a transmitter 1040 configured to generate an RF transmit signal. The transmitter 1040 may use the antenna element 1050 or another antenna element (not illustrated) of the mobile device 1000 for radiating the RF transmit signal to the environment. For example, the transmitter 1040 may be coupled to the antenna element 1050 via one or more intermediate elements such as a filter, an up-converter (mixer) or a PA.

To this end, a mobile device with improved undersampled digital input signal processing may be provided allowing the mobile user equipment to meet high performance targets at lower power consumption and lower area consumption.

The mobile user equipment 1000 may comprise further elements such as, e.g., a baseband processor, memory, a connectivity module, a Near Field Communication (NFC) controller, an audio driver, a camera driver, a touch screen, a display driver, sensors, removable memory, a power management integrated circuit or a smart battery.

In some aspects, the application processor may include one or more CPU cores and one or more of cache memory, an LDO voltage regulator, interrupt controllers, serial interfaces such as SPI, I²C, or universal programmable serial interface module, RTC, timer-counters including interval and watchdog timers, general purpose IO, memory card controllers such as SD/MMC or similar, USB interfaces, MIPI interfaces and JTAG test access ports.

In some aspects, the baseband processor may be implemented, for example, as a solder-down substrate including one or more integrated circuits, a single packaged integrated circuit soldered to a main circuit board or a multi-chip module containing two or more integrated circuits.

The wireless communication circuits using the undersampled digital input signal processing according to the proposed architecture or one or more of the examples described above may be configured to operate according to one of the 3rd Generation Partnership Project (3GPP)-standardized mobile communication networks or systems. The mobile or wireless communication system may correspond to, for example, a 5th Generation New Radio (5G NR), a Long-Term Evolution (LTE), an LTE-Advanced (LTE-A), High Speed Packet Access (HSPA), a Universal Mobile Telecommunication System (UMTS) or a UMTS Terrestrial Radio Access Network (UTRAN), an evolved-UTRAN (e-UTRAN), a Global System for Mobile communication (GSM), an Enhanced Data rates for GSM Evolution (EDGE) network, or a GSM/EDGE Radio Access Network (GERAN). Alternatively, the wireless communication circuits may be configured to operate according to mobile communication networks with different standards, for example, a Worldwide Inter-operability for Microwave Access (WIMAX) network IEEE 802.16 or Wireless Local Area Network (WLAN) IEEE 802.11, generally an Orthogonal Frequency Division Multiple Access (OFDMA) network, a Time Division Multiple Access (TDMA) network, a Code Division Multiple Access (CDMA) network, a Wideband-CDMA (WCDMA) network, a Frequency Division Multiple Access (FDMA) network, a Spatial Division Multiple Access (SDMA) network, etc.

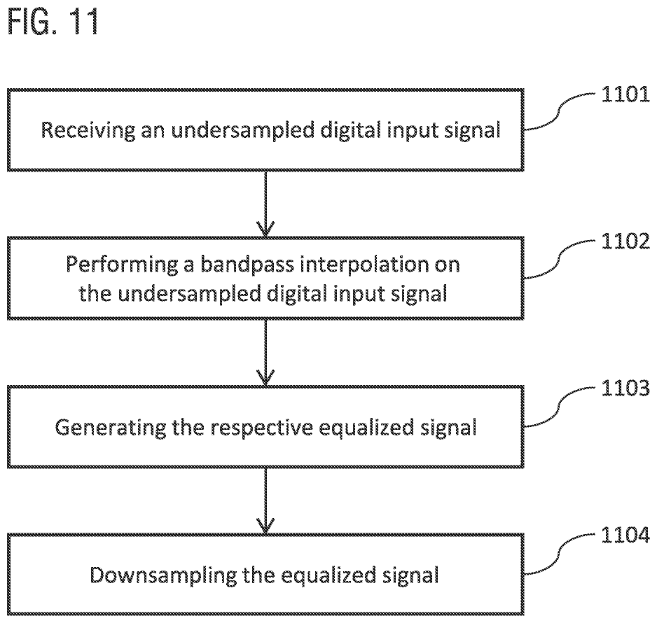

For further illustrating the undersampled digital input signal processing described above, FIG. 11 illustrates a flowchart of a method 1100 for processing an undersampled digital input signal. The method 1100 comprises receiving the undersampled digital input signal 1101 at an input node. In addition, the method 1100 comprises performing a bandpass interpolation on the undersampled digital input signal 1102 generating an interpolated digital input signal. Further, the method 1100 comprises generating an equalized signal from the respective interpolated digital input signal 1103. The method 1100 comprises downsampling the equalized signal 1104.

The method 1100 may enable improved undersampled digital signal processing allowing to meet desirable reconstruction requirements at lower power consumption. As described above, undersampled digital signal processing may be enabled by the method 1100 as the proposed undersampled digital signal processing allows to use lower sample rate by selecting Nyquist zone M where M is greater than 1 and cancel non-linearities by using the non-linear equalizer.

More details and aspects of the method 1100 are explained in connection with the proposed technique or one or more examples described above (e.g. FIGS. 1 to 10). The method 1100 may comprise one or more additional optional features corresponding to one or more aspects of the proposed technique or one or more examples described above.

The examples described herein may be summarized as follows: In a further example (e.g. example 1), an apparatus for processing an undersampled digital input signal, comprising: an input node configured to receive the undersampled digital input signal; a first circuitry configured to perform a bandpass interpolation on the undersampled digital input signal to generate an interpolated digital signal using an interpolation factor based on a Nyquist zone M selected from multiple Nyquist zones, M being greater than 1; a non-linear equalizer to generate an equalized signal from the interpolated digital signal; and a second circuitry configured to downsample the equalized signal to a sample rate of the undersampled digital input signal.

Another example (e.g. example 2) relates to a previously described example (e.g. example 1), wherein an interpolation factor is MN, wherein N indicates an order of non-linear disturbances to be filtered and/or to be corrected by the non-linear equalizer.

Another example (e.g. example 3) relates to a previously described example (e.g. example 1), wherein the interpolated digital signal is bandwidth-limited within the selected Nyquist zone M.

Another example (e.g. example 4) relates to a previously described example (e.g. any one of example 1 to 3), wherein M is selected such that an analogue signal having a center frequency and a bandwidth B is located within the selected Nyquist zone, the analogue signal being the signal from which the undersampled digital input signal is derived.

$$1 \leq M \leq ⌊ \frac{{F}_{H}}{B} ⌋$$

Another example (e.g., example 5) relates to a previous example (e.g., example 4) or to any other example, further comprising that M is selected such that

$$1 \leq M \leq ⌊ \frac{{F}_{H}}{B} ⌋$$

with F_{H} being the highest frequency within a spectrum of the analogue signal.

Another example (e.g. example 6) relates to a previously described example (e.g. any one of example 2 to 5), wherein kₘₐₓ is a maximum order of non-linearity to be filtered and/or to be corrected by the non-linear equalizer and N is equal to or greater than kₘₐₓ.

Another example (e.g. example 7) relates to a previously described example (e.g. any one of examples 2 to 6), wherein a signal having a the center frequency and a bandwidth B is located within a Nyquist zone Mᵣₑₐₗ and M is equal to or greater than (k+1)/2 wherein k is a maximum order of non-linearity of interest and M<Mᵣₑₐₗ.

Another example (e.g. example 8) relates to a circuitry, comprising: a non-linear system coupled to an apparatus according to a previously described example (e.g. any of examples 1 to 7) and configured to output an undersampled digital input signal.

Another example (e.g. example 9) relates to a previously described example (e.g. example 8), wherein the non-linear system comprises an ADC configured to output the undersampled digital input signal.

Another example (e.g. example 10) relates to a previously described example (e.g. example 8 or 9), comprising a receive signal input configured to provide an analog receive signal to the ADC.

Another example (e.g., example 11) relates to a previous example (e.g., example 10) or to any other example, wherein the analogue receive signal is a baseband signal of a receiver of a mobile telecommunications device.

Another example (e.g. example 12) relates to a base station, comprising a circuitry according to a previously described example (e.g. any of example 8 to 11).

Another example (e.g., example 13) relates to a previous example (e.g., example 12) or to any other example, further comprising an Analog-to-Digital Converter, ADC, configured to output the undersampled digital input signal.

Another example (e.g., example 14) relates to a previous example (e.g., example 13) or to any other example, further comprising a radio frequency frontend configured to provide a baseband signal as an input to the ADC.

Another example (e.g. example 15) relates to a mobile user equipment comprising a circuitry according to a previously described example (e.g. any of examples 8 to 11).

Another example (e.g., example 16) relates to a previous example (e.g., example 15) or to any other example, further comprising that the interpolation factor is MN, wherein N indicates an order of non-linear disturbances to be filtered and/or to be corrected by equalizing.

Another example (e.g., example 17) relates to a previous example (e.g., example 16) or to any other example, further comprising that the interpolated digital signal is bandwidth-limited within the selected Mth Nyquist zone M.

Another example (e.g., example 18) relates to a previous example (e.g., any of examples 15 to 17) or to any other example, further comprising selecting M such that an analogue signal having a center frequency and a bandwidth B is located within the selected Nyquist zone, the analogue signal being the signal from which the undersampled digital input signal is derived.

$$1 \leq M \leq ⌊ \frac{{F}_{H}}{B} ⌋$$

Another example (e.g., example 19) relates to a previous example (e.g., e.g., any of examples 15 to 17) or to any other example, further comprising selecting M such that

$$1 \leq M \leq ⌊ \frac{{F}_{H}}{B} ⌋$$

with F_{H} being the highest frequency within a spectrum of the analogue signal.

Another example (e.g. example 20) relates to a method for processing an undersampled digital input signal, comprising: receiving the undersampled digital input signal at an input node; performing a bandpass interpolation on the undersampled digital input signal using an upsampling factor depending on a Nyquist zone M selected from multiple Nyquist zones, M being greater than 1; generating an equalized signal from the interpolated digital signal; and downsampling the equalized signal to a sample rate of the undersampled digital input signal.

Another example (e.g. example 21) relates to a previously described example (e.g. example 12), wherein the interpolation factor is MN, wherein N indicates an order of non-linear disturbances to be filtered and/or to be corrected by equalizing.

Another example (e.g. example 22) relates to a previously described example (e.g. any of example 20 and 21), wherein the interpolated digital signal is bandwidth-limited within the selected Mth Nyquist zone M.

Another example (e.g. example 23) relates to a computer program having a program code configured to, when executed by a processor, perform a method of any one of examples 20 to 22.

Another example (e.g. example 24) relates to a computer readable storage medium having stored thereon a computer program having a program code configured to, when executed by a processor, perform a method of any one of examples 20 to 22.

More details and aspects of the method are mentioned in connection with the proposed concept or one or more examples described above (e.g. FIGS. 1-8). The method may comprise one or more additional optional features corresponding to one or more aspects of the proposed concept or one or more examples described above.

A block diagram may, for instance, illustrate a high-level circuit diagram implementing the principles of the disclosure. Similarly, a flow chart, a flow diagram, a state transition diagram, a pseudo code, and the like may represent various processes, operations or steps, which may, for instance, be substantially represented in computer readable medium and so executed by a computer or processor, whether or not such computer or processor is explicitly shown. Methods disclosed in the specification or in the claims may be implemented by a device having means for performing each of the respective acts of these methods.

It is to be understood that the disclosure of multiple acts, processes, operations, steps or functions disclosed in the specification or claims may not be construed as to be within the specific order, unless explicitly or implicitly stated otherwise, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

Furthermore, the following claims are hereby incorporated into the detailed description, where each claim may stand on its own as a separate example. While each claim may stand on its own as a separate example, it is to be noted that—although a dependent claim may refer in the claims to a specific combination with one or more other claims—other examples may also include a combination of the dependent claim with the subject matter of each other dependent or independent claim. Such combinations are explicitly proposed herein unless it is stated that a specific combination is not intended. Furthermore, it is intended to include also features of a claim to any other independent claim even if this claim is not directly made dependent to the independent claim.

What is claimed is:

1. An apparatus for processing an undersampled digital input signal, comprising:
an input node configured to receive the undersampled digital input signal;
a first circuitry configured to perform a bandpass interpolation on the undersampled digital input signal to generate an interpolated digital signal using an interpolation factor based on a Nyquist zone M selected from multiple Nyquist zones, M being greater than 1;
a non-linear equalizer to generate an equalized signal from the interpolated digital signal; and
a second circuitry configured to downsample the equalized signal to a sample rate of the undersampled digital input signal.

2. The apparatus of claim 1, wherein the interpolation factor is MN, wherein N indicates an order of non-linear disturbances to be filtered and/or to be corrected by the non-linear equalizer.

3. The apparatus of claim 1, wherein the interpolated digital signal is bandwidth-limited within the selected Nyquist zone M.

4. The apparatus of claim 1, wherein M is selected such that an analogue signal having a center frequency and a bandwidth B is located within the selected Nyquist zone, the analogue signal being the signal from which the undersampled digital input signal is derived.

5. The apparatus of claim 4, wherein M is selected such that
$$1 \leq M \leq ⌊ \frac{{F}_{H}}{B} ⌋$$
with FH being the highest frequency within a spectrum of the analogue signal.

6. The apparatus of claim 2, wherein kₘₐₓ is a maximum order of non-linearity to be filtered and/or to be corrected by the non-linear equalizer and N is equal to or greater than kₘₐₓ.

7. The apparatus of claim 2, wherein a signal having a the center frequency and a bandwidth B is located within a Nyquist zone Mᵣₑₐₗ and M is equal to or greater than (k+1)/2 wherein k is a maximum order of non-linearity of interest and M<Mᵣₑₐₗ.

8. The apparatus of claim 1, further comprising:
a non-linear system coupled to input node and configured to output the undersampled digital input signal.

9. The apparatus of claim 8, wherein the non-linear system comprises an Analog-to-Digital Converter, ADC, configured to output the undersampled digital input signal.

10. The apparatus of claim 9, further comprising a receive signal input configured to provide an analogue receive signal to the ADC.

11. The apparatus of claim 10, wherein the analogue receive signal is a baseband signal of a receiver of a mobile telecommunications device.

12. A base station or a mobile user equipment, comprising:
an input node configured to receive an undersampled digital input signal;
a first circuitry configured to perform a bandpass interpolation on the undersampled digital input signal to generate an interpolated digital signal using an interpolation factor depending on a Nyquist zone M selected from multiple Nyquist zones, M being greater than 1;
a non-linear equalizer to generate an equalized signal from the interpolated digital signal; and
a second circuitry configured to downsample the equalized signal to a sample rate of the undersampled digital input signal.

13. The base station of claim 12, further comprising an Analog-to-Digital Converter, ADC, configured to output the undersampled digital input signal.

14. The base station of claim 13, further comprising a radio frequency frontend configured to provide a baseband signal as an input to the ADC.

15. A computer readable storage medium having stored thereon a computer program having a program code configured to, when executed by a processor, perform a method comprising:
receiving the undersampled digital input signal at an input node;
performing a bandpass interpolation on the undersampled digital input signal using an interpolation factor depending on a Nyquist zone M selected from multiple Nyquist zones, M being greater than 1;
generating an equalized signal from the interpolated digital signal; and
downsampling the equalized signal to a sample rate of the undersampled digital input signal.

16. The computer readable storage medium of claim 15, wherein the interpolation factor is MN, wherein N indicates an order of non-linear disturbances to be filtered and/or to be corrected by equalizing.

17. The computer readable storage medium of claim 16, wherein the interpolated digital signal is bandwidth-limited within the selected Mth Nyquist zone M.

18. The computer readable storage medium of claim 15, wherein M is selected such that an analogue signal having a center frequency and a bandwidth B is located within the selected Nyquist zone, the analogue signal being the signal from which the undersampled digital input signal is derived.

19. The computer readable storage medium of claim 18, wherein M is selected such that
$$1 \leq M \leq ⌊ \frac{{F}_{H}}{B} ⌋$$
with FH being the highest frequency within a spectrum of the analogue signal.
